(19) United States
(12) Patent Application Publication
(10) Pub. No.: US 2012/0126096 A1
(43) Pub. Date: May 24, 2012

(54) SOLID-STATE IMAGING DEVICE AND MANUFACTURING METHOD OF SOLID-STATE IMAGING DEVICE

(75) Inventors: Yuki SUGIURA, Oita (JP); Takeo Nakayama, Kanagawa (JP)

(73) Assignee: KABUSHIKI KAISHA TOSHIBA, Tokyo (JP)

(21) Appl. No.: 13/299,854

(22) Filed: Nov. 18, 2011

(30) Foreign Application Priority Data
Nov. 22, 2010 (JP) 2010-259966

(51) Int. Cl. H01L 27/146; H01L 31/18

(52) U.S. Cl. 250/208.1; 438/58; 257/E31.11

(57) ABSTRACT

According to one embodiment, a semiconductor layer in which a photoelectric conversion unit is formed for each pixel, a readout circuit that is formed on a front side of the semiconductor layer and reads out a signal from the photoelectric conversion unit, a light incident surface provided on a back side of the photoelectric conversion unit, and a gettering layer provided on a front side of the photoelectric conversion unit are included.

### CROSS-REFERENCE TO RELATED APPLICATIONS

This application is based upon and claims the benefit of priority from Japanese Patent Application No. 2010-259966, filed on Nov. 22, 2010; the entire contents of which are incorporated herein by reference.

### FIELD

Embodiments described herein relate generally to a solid-state imaging device and a manufacturing method of a solid-state imaging device.

### BACKGROUND

In solid-state imaging devices, when a substrate is contaminated with heavy metal such as Cu, Fe, and Ni during a manufacturing process, a deep level is formed in a forbidden band and a dark current flows, so that a white spot is generated. There is a method called gettering for preventing heavy metal contamination, however, if a gettering layer is formed in a photosensitive surface for increasing the gettering efficiency, the sensitivity decreases.

### BRIEF DESCRIPTION OF THE DRAWINGS

FIG. 1 is a cross-sectional view illustrating a schematic configuration of a solid-state imaging device according to a first embodiment;

FIG. 2A to FIG. 2D are cross-sectional views illustrating a manufacturing method of a solid-state imaging device according to a second embodiment;

FIG. 3A to FIG. 3D are cross-sectional views illustrating the manufacturing method of the solid-state imaging device according to the second embodiment;

FIG. 4A to FIG. 4D are cross-sectional views illustrating the manufacturing method of the solid-state imaging device according to the second embodiment;

FIG. 5A to FIG. 5D are cross-sectional views illustrating the manufacturing method of the solid-state imaging device according to the second embodiment;

FIG. 6A to FIG. 6C are cross-sectional views illustrating the manufacturing method of the solid-state imaging device according to the second embodiment;

FIG. 7 is a cross-sectional view illustrating a schematic configuration of a solid-state imaging device according to a third embodiment; and

FIG. 8A and FIG. 8B are cross-sectional views illustrating a manufacturing method of a solid-state imaging device according to a fourth embodiment.

### DETAILED DESCRIPTION

In general, according to a solid-state imaging device in embodiments, a semiconductor layer, a readout circuit, a light incident surface, and a gettering layer are included. In the semiconductor layer, a photoelectric conversion unit is formed for each pixel. The readout circuit is formed on a front side of the semiconductor layer and reads out a signal from the photoelectric conversion unit. The light incident surface is provided on a back side of the photoelectric conversion unit. The gettering layer is provided on a front side of the photoelectric conversion unit.

A solid-state imaging device and a manufacturing method of a solid-state imaging device according to the embodiments will be explained below with reference to the drawings. The present invention is not limited to these embodiments.

### First Embodiment

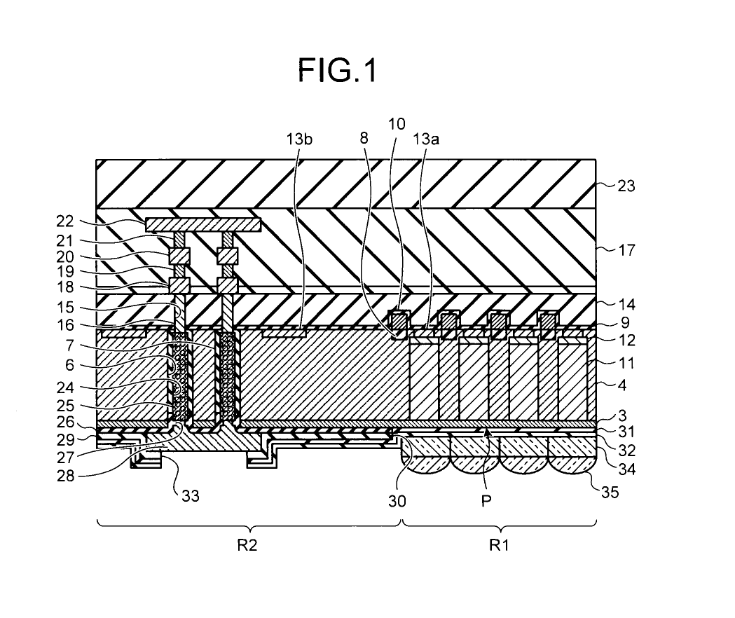

FIG. 1 is a cross-sectional view illustrating a schematic configuration of a solid-state imaging device according to the first embodiment. In the following explanation, a case in which a back-illuminated CMOS image sensor is used as a solid-state imaging device is explained as an example.

In FIG. 1, an N-type semiconductor layer 4 includes a pixel area R1 and a peripheral area R2. In the N-type semiconductor layer 4 of the pixel area R1, an N-type impurity introduced layer 11 is formed for each pixel. Moreover, a P-type impurity introduced layer 12 is formed on the N-type impurity introduced layer 11, whereby a photodiode is formed as a photoelectric conversion unit for each pixel. In the example in FIG. 1, a method of forming a PN diode as the photoelectric conversion unit is explained, however, the photoelectric conversion unit is not limited to a PN diode and, for example, may be a PIN diode or the like.

A P-type semiconductor layer 3, which separates the photoelectric conversion units for each pixel, is formed on the back surface of the N-type semiconductor layer 4, and a light incident surface P is provided on the back side of the photoelectric conversion unit. A single-crystal semiconductor may be used for the P-type semiconductor layer 3 and the N-type semiconductor layer 4.

In the pixel area R1, a color filter 34 is formed for each pixel on the back side of the photoelectric conversion unit via anti-reflective films 31 and 32 and an on-chip lens 35 is formed for each pixel on the color filter 34.

Moreover, in the pixel area R1, gettering layers 13a are formed on the front side of the photoelectric conversion units. The gettering layer 13a is formed on the surface layer of the P-type impurity introduced layer 12. The light incident surface P and the gettering layers 13a can be arranged to face each other with the photoelectric conversion units therebetween. The gettering layer 13a can be formed for each pixel. Moreover, the gettering layer 13a can be arranged to cover part of the surface of a pixel. The gettering layer 13a is preferably separated from a gate electrode 10 by about 0.1 μm to 0.2 μm for preventing the gettering layer 13a from coming into contact with the gate electrode 10.

Moreover, in the pixel area R1, on the front side of the N-type semiconductor layer 4, isolation dielectric layers 8 isolating pixels from each other are embedded and the gate electrodes 10 are formed. A readout circuit, which reads out a signal from the photoelectric conversion unit, can be formed by appropriately wiring the gate electrode 10. As the readout circuit, for example, a row select transistor, an amplifying transistor, a reset transistor, a readout transistor, and a floating diffusion may be provided for each pixel.

On the other hand, in the peripheral area R2, through holes 6 are formed in the P-type semiconductor layer 3 and the N-type semiconductor layer 4, and penetrating electrodes 25 are embedded in the through holes 6 via a through hole dielectric layer 7. On the back side of the N-type semiconductor layer 4, a dielectric layer 26 is formed on the P-type semiconductor layer 3 and a pad electrode 28 is formed on the dielectric layer 26. In the dielectric layer 26, openings 27, which expose the penetrating electrodes 25, are formed, and the pad electrode 28 is connected to the penetrating electrodes 25 through the openings 27.

Furthermore, a dielectric layer 29 is formed on the dielectric layer 26 and an opening 30, which exposes the back side in the pixel area R1, is formed in the dielectric layers 26 and 29. Moreover, the anti-reflective films 31 and 32 are formed on the dielectric layer 29 and an opening 33, which exposes the pad electrode 28, is formed in the dielectric layer 29 and the anti-reflective films 31 and 32.

Moreover, in the peripheral area R2, gettering layers 13b are formed on the front side of the N-type semiconductor layer 4. The gettering layers 13b can be formed in the surface layer of the N-type semiconductor layer 4. As the gettering layers 13a and 13b, an amorphous semiconductor or a polycrystalline semiconductor can be used. As the P-type semiconductor layer 3, the N-type semiconductor layer 4, and the gettering layers 13a and 13b, for example, Si, Ge, SiGe, GaAs, InP, GaP, GaN, SiC, or GaInAsP can be used.

Furthermore, in the pixel area R1 and the peripheral area R2, an interlayer dielectric layer 14 is formed on the front side of the N-type semiconductor layer 4. In the interlayer dielectric layer 14, openings 15, which expose the penetrating electrodes 25, are formed, and embedded electrodes 16 are embedded in the openings 15. An interlayer dielectric layer 17 is stacked on the interlayer dielectric layer 14 and wires 18, 20, and 22 are embedded for each layer in the interlayer dielectric layer 17. The wires 18 and 20 are connected with each other via an embedded electrode 19 and the wires 20 and 22 are connected with each other via an embedded electrode 21. A support substrate 23 is provided on the interlayer dielectric layer 17.

Light, which enters the back side of the N-type semiconductor layer 4, is collected by the on-chip lenses 35 for each pixel and enters the photoelectric conversion units in the N-type semiconductor layer 4 through the color filters 34. Then, when the light enters the photoelectric conversion units, charges are generated in the photoelectric conversion units according to the amount of light and are accumulated in the photoelectric conversion units. Then, in the readout circuits on the front side of the N-type semiconductor layer 4, signals are read out from the photoelectric conversion units, whereby an image signal is output.

The light incident surface P is provided on the back side of the photoelectric conversion units and the gettering layers 13a are provided on the front side of the photoelectric conversion units, so that the gettering layers 13a can be made closer to the photoelectric conversion units while preventing the gettering layers 13a from blocking light that enters the photoelectric conversion units, enabling to improve the gettering efficiency while suppressing decrease in sensitivity.

### Second Embodiment

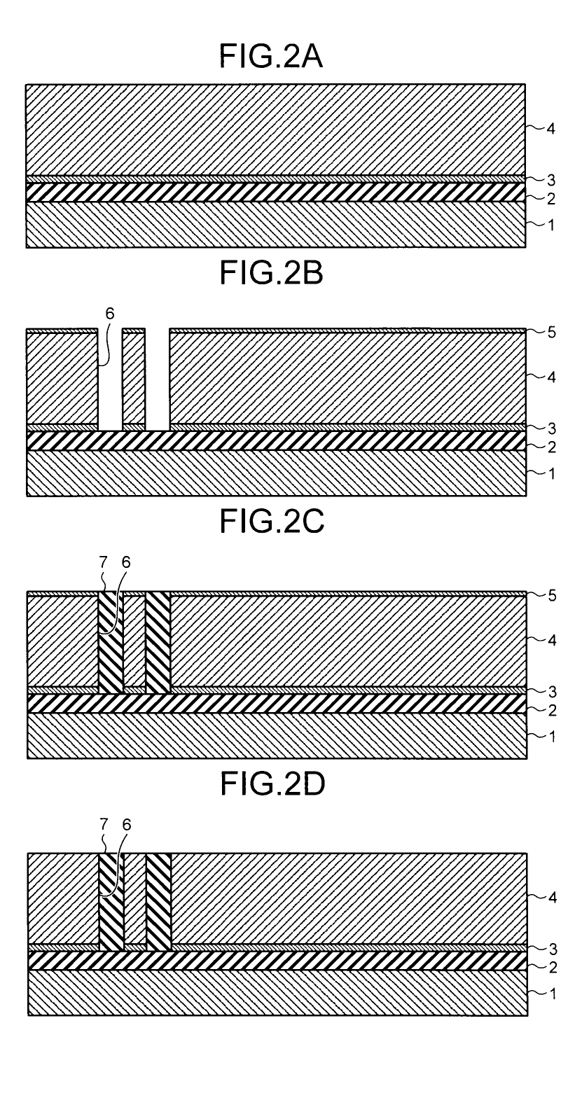

FIG. 2A to FIG. 6C are cross-sectional views illustrating a manufacturing method of a solid-state imaging device according to the second embodiment.

In FIG. 2A, the P-type semiconductor layer 3 and the N-type semiconductor layer 4 are sequentially provided on a semiconductor substrate 1 via a BOX layer 2. As the substrate, in which the P-type semiconductor layer 3 and the N-type semiconductor layer 4 are sequentially provided on the semiconductor substrate 1 via the BOX layer 2, a SOI substrate can be used. For example, Si can be used as the material of the semiconductor substrate 1 and a silicon oxide film can be used as the material of the BOX layer 2.

Next, as shown in FIG. 2B, a stopper layer 5 is stacked on the whole surface of the N-type semiconductor layer 4 by a method such as the CVD. Then, the through holes 6 are formed in the stopper layer 5 and the N-type semiconductor layer 4 by using the photolithography technology and the dry etching technology. For example, a silicon nitride film can be used as the material of the stopper layer 5.

Next, as shown in FIG. 2C, the through hole dielectric layer 7 is stacked on the whole surface of the stopper layer 5 so that the through holes 6 are filled, by a method such as the CVD. Then, the through hole dielectric layer 7 is thinned by a method such as the CMP to remove the through hole dielectric layer 7 on the stopper layer 5. A silicon oxide film can be used as the material of the through hole dielectric layer 7.

Next, as shown in FIG. 2D, the stopper layer 5 on the N-type semiconductor layer 4 is removed by performing etching of the stopper layer 5. When removing the stopper layer 5 on the N-type semiconductor layer 4, the wet etching is preferably performed for preventing the surface of the N-type semiconductor layer 4 from being damaged.

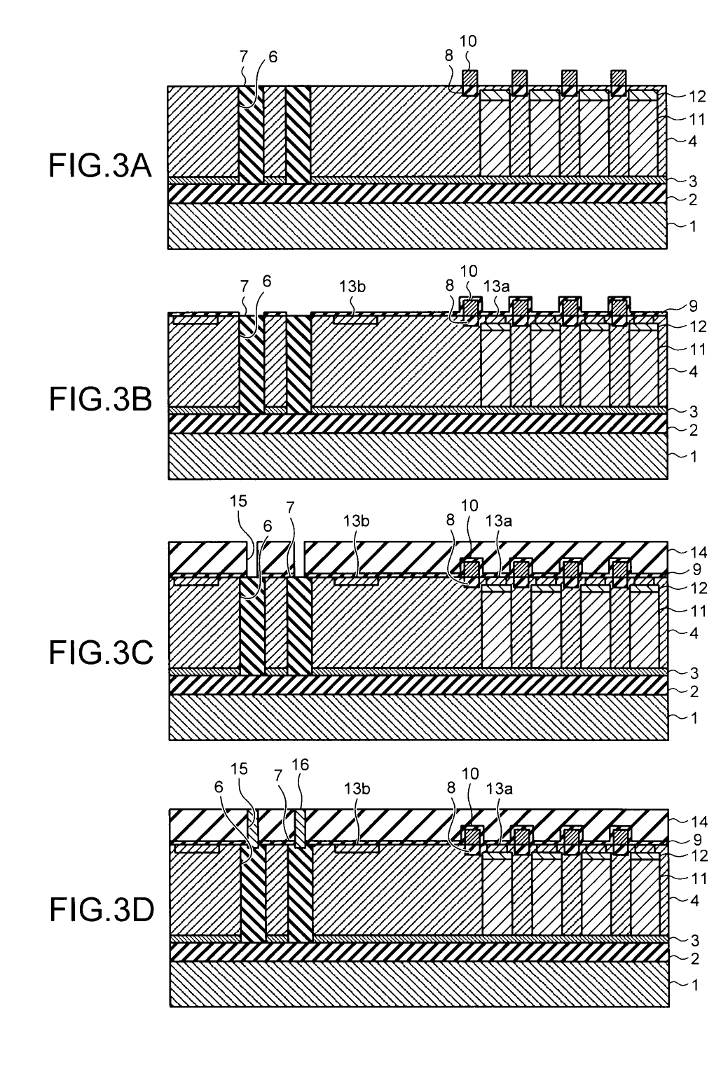

Next, as shown in FIG. 3A, after embedding the isolation dielectric layers 8 arranged between the pixels in the front side of the N-type semiconductor layer 4, the gate electrode 10 is formed for each pixel on the N-type semiconductor layer 4. For example, a silicon oxide film can be used as the material of the isolation dielectric layer 8 and a polycrystalline silicon film can be used as the material of the gate electrode 10.

Then, impurity such as P or As is ion-implanted in the N-type semiconductor layer 4 to form the N-type impurity introduced layers 11 at a deep position in the N-type semiconductor layer 4. Moreover, impurity such as B is ion-implanted in the N-type semiconductor layer 4 to form the P-type impurity introduced layers 12 at a shallow position in the N-type semiconductor layer 4.

The N-type impurity introduced layers 11 and the P-type impurity introduced layers 12 may be formed in the N-type semiconductor layer 4 before forming the gate electrodes 10 on the N-type semiconductor layer 4.

Next, as shown in FIG. 3B, a dielectric film 9 is formed on the surface of the N-type semiconductor layer 4 by the thermal oxidation or the CVD. The film thickness of the dielectric film 9 can be set to about 5 to 6 nm. Then, impurity is selectively ion-implanted in the surface layers of the N-type semiconductor layer 4 and the N-type impurity introduced layers 11 to selectively amorphize the surface layers of the N-type semiconductor layer 4 and the N-type impurity introduced layers 11, thereby forming the gettering layers 13a and 13b in the front side of the N-type semiconductor layer 4. As the impurity used for the ion implantation at that time, for example, Si, Ge, C, B, or In can be used. The ion implantation can be uniformly performed by forming the dielectric film 9 before performing the ion implantation on the surface layers of the N-type semiconductor layer 4 and the N-type impurity introduced layers 11.

After selectively amorphizing the surface layers of the N-type semiconductor layer 4 and the N-type impurity introduced layers 11, the gettering layers 13a and 13b may be polycrystallized by performing a thermal treatment. Defects entered the deep position at the time of the ion implantation can be removed by performing a thermal treatment of polycrystallizing the gettering layers 13a and 13b, enabling to improve the crystal quality of the photoelectric conversion units formed in the N-type semiconductor layer 4.

Next, as shown in FIG. 3C, the interlayer dielectric layer 14 is stacked on the whole surface of the N-type semiconductor layer 4 by a method such as the CVD. Then, the openings 15, which expose the through hole dielectric layer 7, are formed in the dielectric film 9 and the interlayer dielectric layer 14 by using the photolithography technology and the dry etching technology. For example, a silicon oxide film can be used as the material of the N-type semiconductor layer 4. When the dielectric film 9 and the interlayer dielectric layer 14 are made of the same material, the dielectric film 9 and the interlayer dielectric layer 14 can be integrally formed.

Next, as shown in FIG. 3D, the embedded electrode 16 is formed on the whole surface of the interlayer dielectric layer 14 so that the openings 15 are filled, by a method such as the CVD. Then, the embedded electrode 16 is thinned by a method such as the CMP to remove the embedded electrode 16 on the interlayer dielectric layer 14. For example, W, Al, or Cu can be used as the material of the embedded electrode 16.

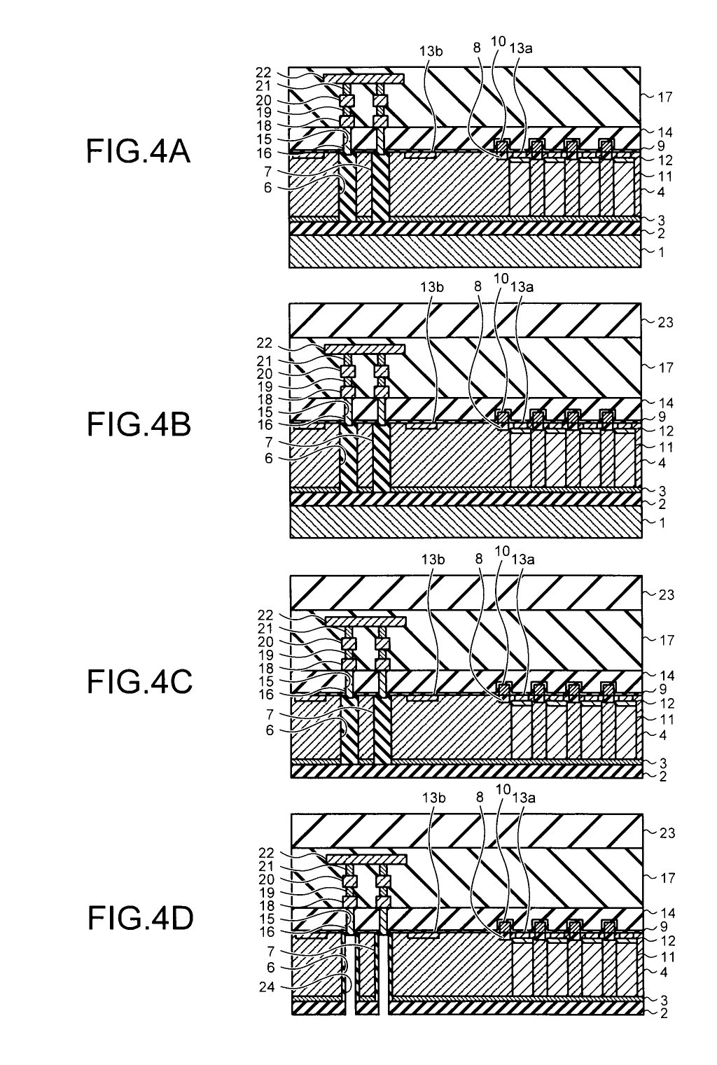

Next, as shown in FIG. 4A, the interlayer dielectric layer 17 is stacked on the whole surface of the interlayer dielectric layer 14 by a method such as the CVD and the wires 18, 20, and 22 and the embedded electrodes 19 and 21 embedded in the interlayer dielectric layer 17 are formed. For example, a silicon oxide film can be used as the material of the interlayer dielectric layer 14, Al or Cu can be used as the material of the wires 18, 20, and 22, and W, Al, Cu, or the like can be used as the material of the embedded electrodes 19 and 21.

Next, as shown in FIG. 4B, the support substrate 23 is formed on the interlayer dielectric layer 17. The support substrate 23 may be attached on the interlayer dielectric layer 17. For example, as the material of the support substrate 23, a semiconductor substrate such as Si may be used or a dielectric substrate, such as glass, ceramic, or resin, may be used.

Next, as shown in FIG. 4C, the semiconductor substrate 1 is thinned by a method such as the CMP to remove the semiconductor substrate 1 from the back surface of the BOX layer 2. The BOX layer 2 can be used as a stop layer when thinning the semiconductor substrate 1.

Next, as shown in FIG. 4D, openings 24, which expose the embedded electrodes 16, are formed in the through hole dielectric layer 7 by using the photolithography technology and the dry etching technology. At this time, the through hole dielectric layer 7 can be left on the side surfaces of the through holes 6.

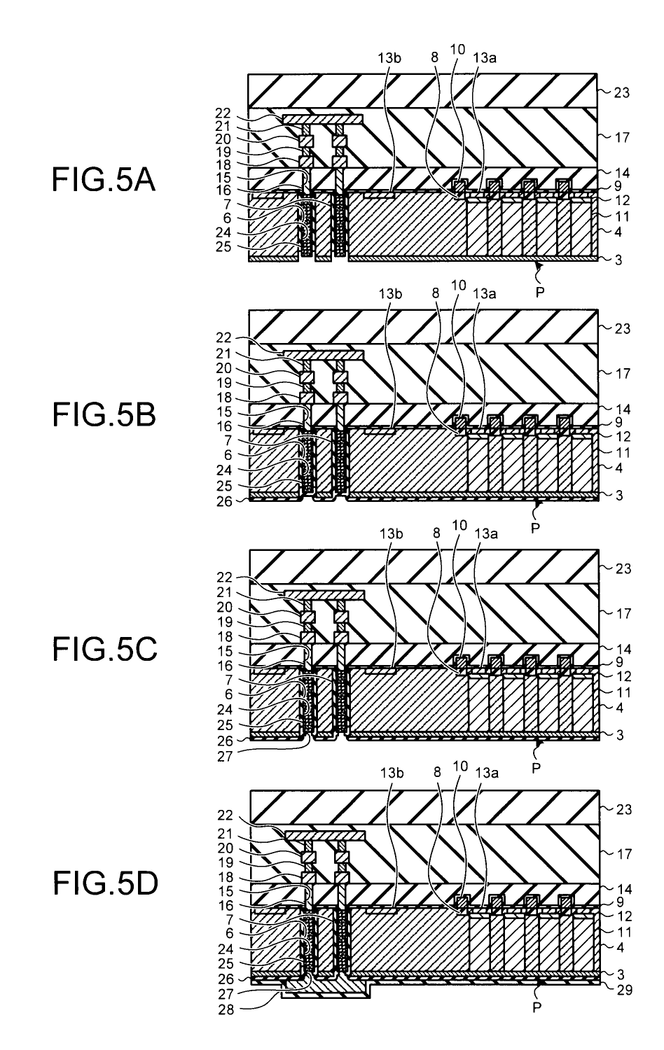

Next, as shown in FIG. 5A, the penetrating electrode 25 is formed on the back surface of the BOX layer 2 so that the openings 24 are filled, by a method such as plating or the CVD. Then, the penetrating electrode 25 is thinned by a method such as the CMP to remove the penetrating electrode 25 on the back surface of the BOX layer 2. For example, W, Al, or Cu can be used as the material of the penetrating electrode 25. Thereafter, the BOX layer 2 is removed from the back surface of the N-type semiconductor layer 4 by performing etching of the BOX layer 2 and the light incident surface P is provided on the back surface of the N-type semiconductor layer 4.

Next, as shown in FIG. 5B, the dielectric layer 26 is formed on the back surface of the N-type semiconductor layer 4 by a method such as the CVD. For example, a silicon oxide film can be used as the material of the dielectric layer 26.

Next, as shown in FIG. 5C, the openings 27, which expose the penetrating electrodes 25, are formed in the dielectric layer 26, by using the photolithography technology and the dry etching technology.

Next, as shown in FIG. 5D, the pad electrode 28 connected to the penetrating electrodes 25 through the openings 27 is formed on the dielectric layer 26. Thereafter, the dielectric layer 29 is formed on the whole surface of the dielectric layer 26 by a method such as the CVD. For example, a silicon oxide film can be used as the material of the dielectric layer 29.

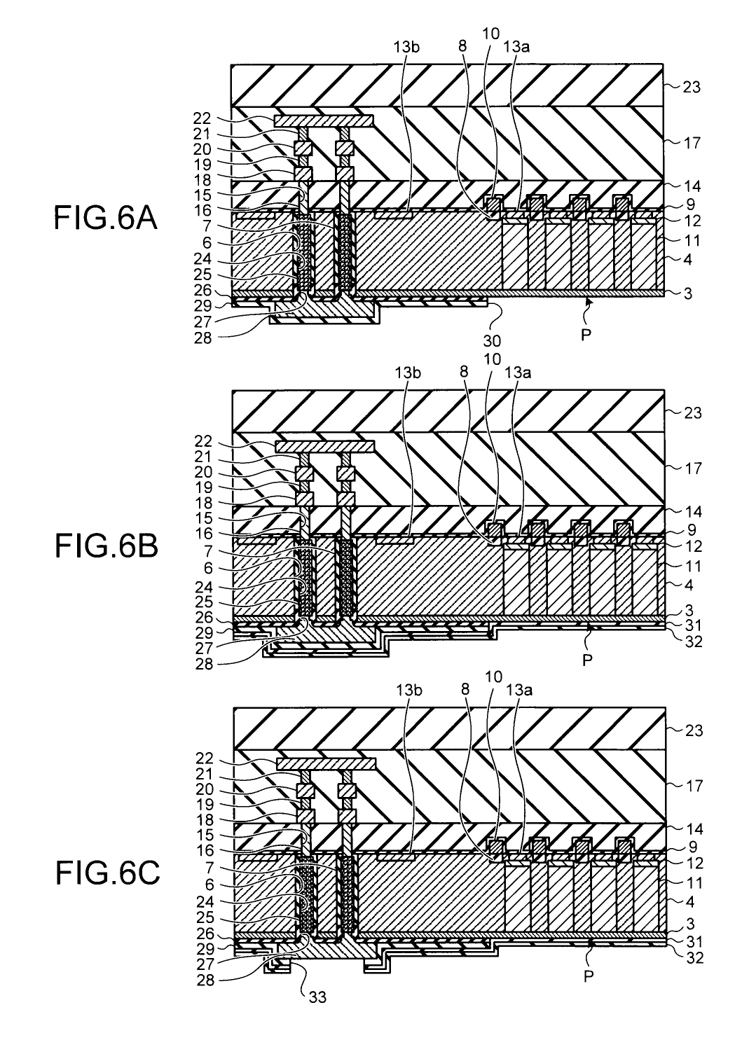

Next, as shown in FIG. 6A, the opening 30, which exposes the pixel area R1 of the back surface of the N-type semiconductor layer 4, is formed in the dielectric layers 26 and 29, by using the photolithography technology and the dry etching technology.

Next, as shown in FIG. 6B, the anti-reflective films 31 and 32 are sequentially formed on the back side of the N-type semiconductor layer 4 by a method such as the CVD or sputtering. For example, a silicon oxide film can be used as the material of the anti-reflective films 31 and 32. At this time, the refractive indexes of the anti-reflective films 31 and 32 can be made different from each other.

Next, as shown in FIG. 6C, the opening 33, which exposes the pad electrode 28, is formed in the anti-reflective films 31 and 32, by using the photolithography technology and the dry etching technology.

Next, as shown in FIG. 1, after forming the color filter 34 for each pixel on the anti-reflective film 32, the on-chip lens 35 is formed for each pixel on the color filter 34. For example, a transparent organic compound can be used as the material of the color filter 34 and the on-chip lens 35. At this time, the color filter 34 can be colored, for example, red, green, or blue.

The gettering layers 13a are formed by ion implantation, so that the gettering layers 13a can be selectively arranged on the front side of the photoelectric conversion units without performing etching for patterning the gettering layers 13a, enabling to make the gettering layers 13a closer to the photoelectric conversion units and prevent the photoelectric conversion units from being damaged due to etching of the gettering layers 13a.

In the above embodiment, explanation is given for the method of forming a back-illuminated CMOS image sensor by using a SOI substrate, however, it is possible to apply to a method of forming a back-illuminated CMOS image sensor by using a bulk epi substrate.

### Third Embodiment

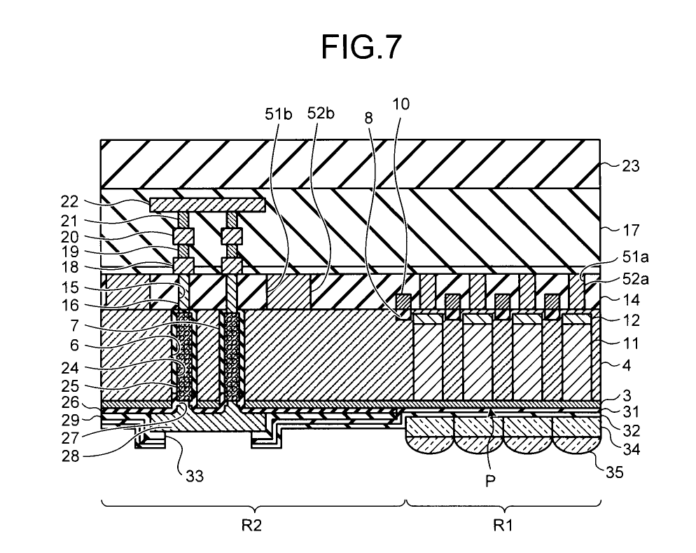

FIG. 7 is a cross-sectional view illustrating a schematic configuration of a solid-state imaging device according to the third embodiment.

In FIG. 7, in this solid-state imaging device, gettering layers 52a and 52b are provided on the front side of the photoelectric conversion units instead of the gettering layers 13a and 13b in FIG. 1. In the interlayer dielectric layer 14, openings 51a and 51b, which expose the surfaces of the N-type impurity introduced layers 11 and the N-type semiconductor layer 4, respectively, are formed. The gettering layers 52a and 52b are embedded in the openings 51a and 51b to be in contact with the N-type impurity introduced layers 11 and the N-type semiconductor layer 4, respectively. The opening 51a can be formed for each pixel. The opening 51a can be arranged to cover part of the surface of a pixel.

An interval can be provided between the gettering layer 52a and the gate electrode 10 for preventing the gettering layers 52a from coming into contact with the gate electrodes 10. As the gettering layers 52a and 52b, an amorphous semiconductor or a polycrystalline semiconductor can be used. Moreover, as the gettering layers 52a and 52b, for example, Si, Ge, SiGe, GaAs, InP, GaP, GaN, SiC, or GaInAsP can be used.

The light incident surface P is provided on the back side of the photoelectric conversion units and the gettering layers 52a are provided on the front side of the photoelectric conversion units, so that the gettering layers 52a can be made closer to the photoelectric conversion units while preventing the gettering layers 52a from blocking light that enters the photoelectric conversion units, enabling to improve the gettering efficiency while suppressing decrease in sensitivity.

### Fourth Embodiment

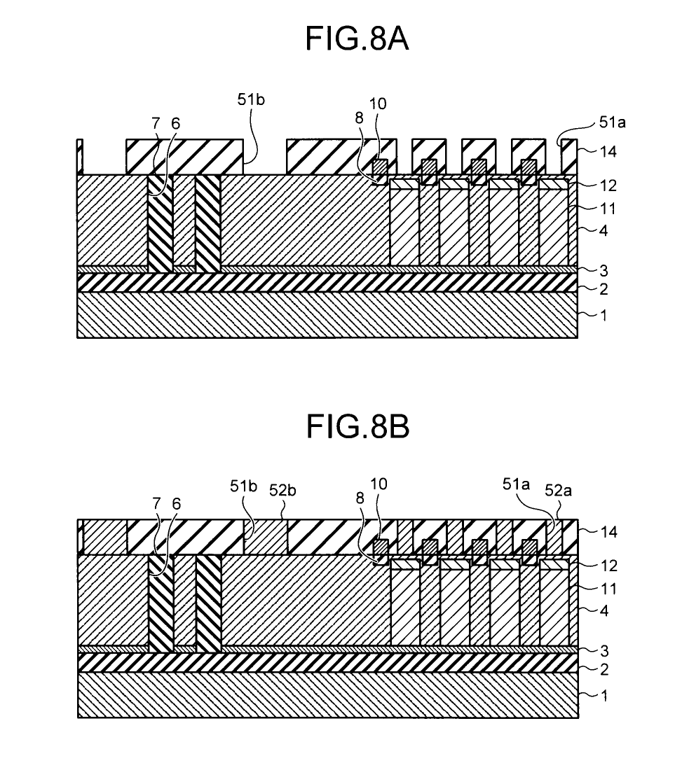

FIG. 8A and FIG. 8B are cross-sectional views illustrating a manufacturing method of a solid-state imaging device according to the fourth embodiment.

In FIG. 8A, after finishing the process in FIG. 3B, the interlayer dielectric layer 14 is stacked on the whole surface of the N-type semiconductor layer 4 by a method such as the CVD. Then, the openings 51a and 51b, which expose the surfaces of the N-type impurity introduced layers 11 and the N-type semiconductor layer 4, respectively, are formed in the interlayer dielectric layer 14 by using the photolithography technology and the dry etching technology.

Next, as shown in FIG. 8B, the gettering layers 52a and 52b are formed on the whole surface of the interlayer dielectric layer 14 so that the openings 51a and 51b are filled, by a method such as the CVD. Then, the gettering layers 52a and 52b are thinned by a method such as the CMP to remove the gettering layers 52a and 52b on the interlayer dielectric layer 14. Thereafter, the process proceeds to the process in FIG. 3C and the subsequent processes.

The gettering layers 52a are formed by the CVD, so that the gettering layers 52a can be made closer to the photoelectric conversion units while enabling to easily thicken the gettering layers 52a, so that the gettering efficiency can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a semiconductor layer in which a photoelectric conversion unit is formed for each pixel;
a readout circuit that is formed on a front side of the semiconductor layer and reads out a signal from the photoelectric conversion unit;
a light incident surface provided on a back side of the photoelectric conversion unit; and
a gettering layer provided on a front side of the photoelectric conversion unit.

2. The solid-state imaging device according to claim 1, further comprising:
a dielectric film provided on the gettering layer; and
an inter-layer dielectric film formed on the dielectric film.

3. The solid-state imaging device according to claim 1, wherein the light incident surface and the gettering layer are arranged to face each other with the photoelectric conversion unit therebetween.

4. The solid-state imaging device according to claim 1, wherein
the semiconductor layer is a single-crystal semiconductor, and
the gettering layer is an amorphous semiconductor or a polycrystalline semiconductor.

5. The solid-state imaging device according to claim 1, wherein the gettering layer is provided for each pixel.

6. The solid-state imaging device according to claim 5, wherein the gettering layer is arranged to cover part of a surface of the pixel.

7. The solid-state imaging device according to claim 1, wherein
the pixel includes
an N-type impurity introduced layer formed in the semiconductor layer, and
a P-type impurity introduced layer that is formed in the semiconductor layer and is arranged on the N-type impurity introduced layer.

8. The solid-state imaging device according to claim 7, wherein the gettering layer is formed in a surface layer of the n-type impurity introduced layer.

9. The solid-state imaging device according to claim 1, further comprising a color filter provided on the back side of the photoelectric conversion unit for each pixel.

10. The solid-state imaging device according to claim 9, further comprising an on-chip lens provided on the back side of the photoelectric conversion unit for each pixel.

11. The solid-state imaging device according to claim 1, further comprising:
a pad electrode that is formed on a back side of the semiconductor layer and is arranged in a peripheral area of the photoelectric conversion unit; and
a penetrating electrode that is connected to the pad electrode and is embedded in the semiconductor layer.

12. A solid-state imaging device comprising:
a semiconductor layer in which a photoelectric conversion unit is formed for each pixel;
a readout circuit that is formed on a front side of the semiconductor layer and reads out a signal from the photoelectric conversion unit;
a light incident surface provided on a back side of the photoelectric conversion unit;
an inter-layer dielectric film formed on a front side of the photoelectric conversion unit and on the readout circuit; and
a gettering layer embedded in the inter-layer dielectric film.

13. The solid-state imaging device according to claim 12, wherein
the semiconductor layer is a single-crystal semiconductor, and
the gettering layer is an amorphous semiconductor or a polycrystalline semiconductor.

14. The solid-state imaging device according to claim 12, wherein the gettering layer is provided for each pixel.

15. The solid-state imaging device according to claim 14, wherein the gettering layer is arranged to cover part of a surface of the pixel.

16. The solid-state imaging device according to claim 12, wherein
the pixel includes
an N-type impurity introduced layer formed in the semiconductor layer, and
a P-type impurity introduced layer that is formed in the semiconductor layer and is arranged on the N-type impurity introduced layer.

17. The solid-state imaging device according to claim 16, wherein the gettering layer is formed on the n-type impurity introduced layer.

18. The solid-state imaging device according to claim 12, further comprising:
a color filter provided on the back side of the photoelectric conversion unit for each pixel; and
an on-chip lens provided on the back side of the photoelectric conversion unit for each pixel.

19. The solid-state imaging device according to claim 12, further comprising:
a pad electrode that is formed on a back side of the semiconductor layer and is arranged in a peripheral area of the photoelectric conversion unit; and
a penetrating electrode that is connected to the pad electrode and is embedded in the semiconductor layer.

20. A manufacturing method of a solid-state imaging device, comprising:
forming a photoelectric conversion unit on a front side of a semiconductor layer;
forming a readout circuit that reads out a signal from the photoelectric conversion unit, on the front side of the semiconductor layer;
forming a dielectric layer on a front side of the photoelectric conversion unit;
forming a gettering layer by performing ion-implantation on a surface layer of the photoelectric conversion unit;
forming an inter-layer dielectric film on the dielectric layer; and
providing a light incident surface on a back side of the photoelectric conversion unit.
